(19) United States
(12) Patent Application Publication
(10) Pub. No.: US 2005/0092254 A1
(43) Pub. Date: May 5, 2005

(54) PVD transfer robot short blade

(75) Inventor: Mark Davidson, (US)

Correspondence Address: STAAS & HALSEY LLP, SUITE 700, 1201 NEW YORK AVENUE, N.W., WASHINGTON, DC, 20005, US

(73) Assignee: Infineon Technologies Richmond, LP, Sandston, VA (US)

(21) Appl. No.: 10/697,975

(22) Filed: Oct. 31, 2003

(51) Int. Cl. C23C 16/00

(52) U.S. Cl. 118/728; 427/250

(57) ABSTRACT

An apparatus including a first robot, a blade on the first robot, the blade including a pocket to receive a wafer and self-correct a positioning error of the wafer in the pocket, and a first chamber to receive the wafer from the blade and deposit a first metal on the received wafer.

### BACKGROUND OF THE INVENTION

1. Field of the Invention

The present invention relates to a blade to handle a wafer in a physical vapor deposition (PVD) tool.

2. Description of the Related Art

FIG. 1 is a plan view of a conventional blade 140 used in a PVD tool to process a semiconductor (i.e., silicon) wafer 1 (indicated by a dotted line) by depositing metals thereon to thereby form an IC chip. An example of such a PVD tool is the ENDURA 5500 HP by Applied Materials, Inc. The blade 140 includes a pocket 142 which receives the wafer 1. The diameter of one example of the pocket is 7.685 inches, thus, there is a large gap G between an outer periphery of the pocket 142 and an outer periphery of the wafer 1 (which has a standard size).

The blade 140 also includes a calibration hole 144 which is used by the tool during a known calibration method. The blade 140 also includes a shoe area 150, which is used to attach the blade 140 to the tool.

The dimensions of the pocket 142 of the conventional blade 140 allow for positioning errors of the wafer 1 on the blade 140. Specifically, the diameter of 7.685 inches is too large, thus, the blade 140 may be positioned within this large tolerance of the pocket 142. Thus, during deposition, the wafer 1 is not properly placed, and may stick to the deposition chamber. Specifically, aluminum is deposited on the wafer 1. At a temperature of approximately 440° C., the aluminum is in a reflow stage and is thus extremely sticky. Any positioning error will result in sticking of the reflow aluminum to the deposition ring of the deposition chamber, and the wafer 1 will break when being removed from the chamber. Furthermore, a back side pressure fault occurs when voltage is applied to the improperly placed wafer 1 while in the deposition chamber. This fault results in a discarded wafer. Still further, the blade 140 is made of aluminum, and thus there is little friction between the blade 140 and the wafer 1, thereby allowing the wafer 1 to slide freely to an improper position on the blade.

### SUMMARY OF THE INVENTION

Accordingly, selected embodiments of the present invention overcomes the above disadvantages of the conventional blade.

The present invention could possibly provide a blade that self corrects positioning errors, thereby reducing the amount of lost wafers due to back pressure faults and sticking-related losses.

The present invention also could possibly provide a blade that does not require new calibration and attachment methods, thus, interchangeability with existing blades is achieved.

Additional aspects and advantages of the invention will be set forth in part in the description which follows and, in part, will be obvious from the description, or may be learned by practice of the invention.

The foregoing and other advantages may be achieved by providing a blade to hold a wafer in a PVD tool including a substantially flat portion defining a pocket to receive the wafer and to self-align the wafer on the blade.

The foregoing and other advantages may be achieved by providing an apparatus including a first robot; a blade on the first robot, the blade including a pocket to receive a wafer and self-correct a positioning error of the wafer in the pocket; and a first chamber to receive the wafer from the blade and deposit a first metal on the received wafer.

The foregoing and other advantages may be achieved by providing a method including transferring a wafer from a first robot to a blade having a pocket on a second robot; and self-correcting a positioning error of the wafer on the blade due to the transferring with the pocket.

### BRIEF DESCRIPTION OF THE DRAWINGS

These and other aspects and advantages of the invention will become apparent and more readily appreciated from the following description of the preferred embodiment, taken in conjunction with the accompanying drawings of which:

FIG. 1 is a plan view of a conventional blade;

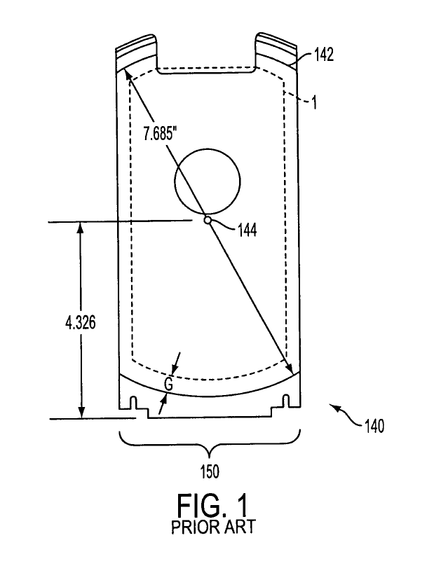

FIG. 2 is a schematic illustration of a PVD tool using the blade according to an embodiment of the present invention;

FIG. 3. is an illustration of a processing chamber of FIG. 2;

FIG. 4 is a plan view of a blade on the transfer robot of FIG. 2 according to the embodiment of the present invention; and

FIG. 5 is a side view of the blade of FIG. 4.

### DETAILED DESCRIPTION OF THE PREFERRED EMBODIMENT

Reference will now be made in detail to the present preferred embodiments of the present invention, examples of which are illustrated in the accompanying drawings, wherein like reference numerals refer to like elements throughout.

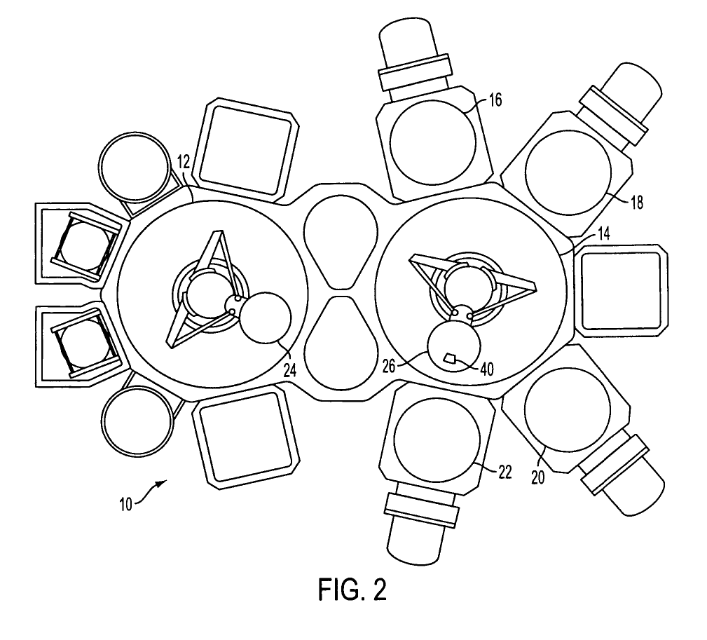

FIG. 2 is a schematic illustration of a PVD tool 10 using a blade 40 according to an embodiment of the present invention. FIG. 2 illustrates a buffer chamber 12 (also called a handling chamber) to receive the wafer 1 from a user, and a transfer chamber 14 to receive the wafer 1 from the buffer chamber 12. A buffer robot 24 receives the wafer 1 from the user and transfers the wafer 1 to a transfer robot 26 for processing. Specifically, the wafer 1 is transferred to the blade 40 of the transfer robot 26. The transfer robot 26 then transfers the wafer 1 to a first processing chamber 16, where a first metal is deposited on the wafer 1. After deposition of the first metal, the transfer robot 26 removes the wafer 1 from the first processing chamber 16 with the blade 40, and transfers the first metal deposited wafer 1 to a second processing chamber 18 and a second metal is deposited thereon. This process continues with respect to third and fourth processing chambers 20 and 22 as well. The first metal is, for example, Al, and the second metal is, for example, Ti. The third and fourth chambers respectively deposit TiN and a second Al layer.

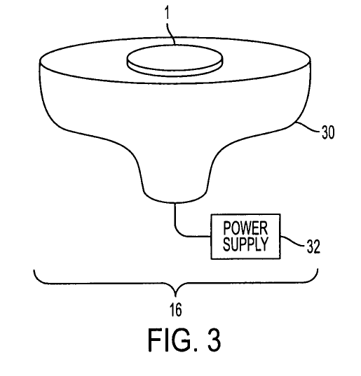

FIG. 3. is a perspective view of the first processing chamber 16 of FIG. 2. The first processing chamber 16 includes an electrostatic chuck 30 (hereinafter echuck) upon which the wafer 1 is placed by the transfer robot 26. The echuck 30 is formed of ceramic and a power supply 32 is connected to the echuck 30 to heat the echuck 30 and apply a voltage to a back side of the wafer 1 to hold the wafer 1 in position. The first processing chamber 16 further includes Argon gas which is excited by another power supply (not shown).

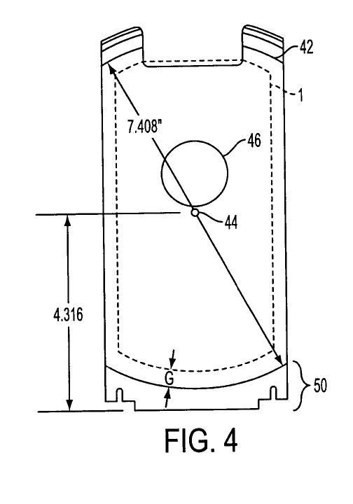

FIG. 4 is a plan view of the blade 40, with a dotted line indicating the position of the wafer 1 thereon. The blade 40 includes a pocket 42 which receives the wafer 1. There is a gap G between an outer periphery of the pocket 42 and an outer periphery of the wafer 1. The pocket 42 is dimensioned so that the gap G is small enough that a positioning error of the wafer 1 on the blade 40 is self-corrected by the blade 40. This positioning error may be during the transferring from the buffer robot 24, or when picking up the wafer 1 from the echuck 30 after deposition. The gap G must also be large enough to accommodate a thermal expansion of the wafer 1 which occurs during the depositing process. According to experiment, a pocket diameter of approximately 7.408″ satisfies these conditions. This diameter is 0.2775″ smaller than the pocket diameter in the conventional blade 140, thus a tighter tolerance is achieved. Although a pocket diameter of 7.408″ is used as an example, this diameter may vary, for example, within +/−0.005″.

The blade 40 also includes a calibration hole 44 which is used by the tool 10 during the known calibration method. Due to the reduction in the pocket diameter, the position of the calibration hole 44 must be moved relative to the top and bottom ends as compared to the conventional blade 140 in order to use this known method. However, the new position of the calibration hole 44 is independent of the change in pocket diameter. According to experiment, the calibration hole is moved 0.01″.

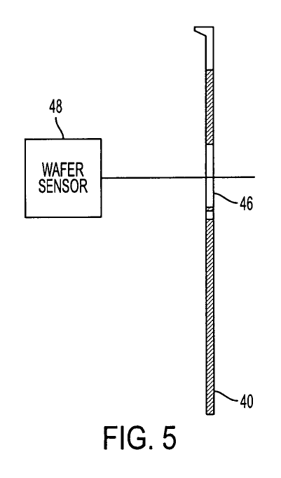

The blade 40 further includes a wafer sensor hole 46 to receive a beam from a wafer sensor 48 (see FIG. 5) to determine whether the wafer 1 has been placed on the blade 40. The blade 40 also includes a shoe area 50, which is used to attach the blade 40 to the transfer robot 26. The shoe area 50 is dimensioned so that the blade 40 may be attached to the transfer robot 26 in a same manner as used for the conventional blade 140.

Furthermore, the blade 40 may be made of aluminum, with a nickel plating to increase friction between the blade 40 and the wafer 1. This allows the blade 40 to maintain the wafer 1 in the correct position.

The blade 40 has the following advantages. First, due to the improved tolerance within the pocket 42, the blade 40 self corrects positioning errors, thereby eliminating lost wafers due to back pressure faults and virtually eliminating sticking-related losses. These advantages are achieved while still accommodating for thermal expansion. In practice, sticking-related losses were reduced by 85%. Furthermore, the blade 40 does not require new calibration and attachment methods, thus, interchangeability with existing blades is achieved. The increased tolerance is achieved without encountering problems due to thermal expansion of the wafer 1.

Although an embodiment of the present invention has been shown and described, it will be appreciated by those skilled in the art that changes may be made in this embodiment without departing from the principles and spirit of the invention, the scope of which is defined in the claims and their equivalents.

1. A blade to hold a wafer in a PVD tool, comprising:
a substantially flat portion defining a pocket to receive the wafer and to self-align the wafer on the blade.

2. The blade of claim 1, wherein a gap between an outer periphery of the pocket and an outer periphery of the wafer is large enough to accommodate a thermal expansion of the wafer while in the PVD tool.

3. The blade of claim 1, wherein a gap between an outer periphery of the pocket and an outer periphery of the wafer is small enough to self-correct an improper placement of the wafer on the blade by the PVD tool.

4. The blade of claim 1, wherein a diameter of the pocket is approximately 7.408 inches +/−0.005″.

5. An physical vapor deposition apparatus comprising:
a first robot;
a blade on the first robot, the blade including a pocket to receive a wafer and self-correct a positioning error of the wafer in the pocket; and
a first chamber to receive the wafer from the blade and deposit a first metal on the received wafer.

6. The apparatus of claim 5, further comprising a second robot to receive the wafer from an outside and transfer the received wafer to the blade, wherein the positioning error is due to the transfer.

7. The apparatus of claim 5, further comprising a second chamber to deposit a second metal on the wafer, wherein the first robot picks up the first metal deposited wafer from the first chamber and transfers the picked up wafer to the second chamber, and the positioning error is due to the pick up.

8. The apparatus of claim 7, wherein the first and second chambers each comprise an electrostatic chuck to accommodate the wafer during the first and second metal depositions.

9. The apparatus of claim 8, wherein the first and second metals are aluminum.

10. The apparatus of claim 5, wherein a diameter of the pocket is approximately 7.408 inches.

11. The apparatus of claim 5, wherein the blade is formed of aluminum with a nickel plating.

12. The apparatus of claim 5, wherein the blade defines a calibration hole therein.

13. The apparatus of claim 5, further comprising a wafer sensor to emit a beam to detect the wafer, wherein the blade further defines a wafer sensor hole therein to receive the emitted beam.

14. A method, comprising:
transferring a wafer from a first robot to a blade having a pocket on a second robot; and
self-correcting a positioning error of the wafer on the blade due to the transferring with the pocket.

15. The method of claim 14, further comprising:
transferring the wafer from the blade to an electrostatic chuck in a first chamber; and
depositing a first metal on the wafer in the first chamber.

16. The method of claim 15, wherein the depositing of the first metal comprises:
heating the wafer with the electrostatic chuck; and
applying a voltage to the wafer to hold the wafer in place on the electrostatic chuck.

17. The method of claim 16, wherein the heating comprises heating the wafer to a reflow temperature of the first metal.

18. The method of claim 17, wherein the first metal at the reflow temperature does not stick to the electrostatic chuck due to the self-correcting of the positioning error.

19. The method of claim 16, further comprising:
picking up the first metal deposited wafer from the first chamber with the blade; and
self-correcting a positioning error of the wafer on the blade due to the picking up with the pocket.

20. The method of claim 19, further comprising: transferring the picked up wafer to a second chamber; and depositing a second metal on the blade in the second chamber.
